(19) United States
(12) Patent Application Publication
(10) Pub. No.: US 2007/0284717 A1
(43) Pub. Date: Dec. 13, 2007

(54) DEVICE EMBEDDED WITH SEMICONDUCTOR CHIP AND STACK STRUCTURE OF THE SAME

(75) Inventors: Chung Cheng Lien, Hsin-chu (TW); Chia-Wei Chang, Hsin-chu (TW)

Correspondence Address: SAWYER LAW GROUP LLP, P O BOX 51418, PALO ALTO, CA, 94303, US

(73) Assignee: PHOENIX PRECISION TECHNOLOGY CORPORATION, Hsin-chu (TW)

(21) Appl. No.: 11/759,204

(22) Filed: Jun. 6, 2007

(30) Foreign Application Priority Data
Jun. 7, 2006 (TW) 095120153

(51) Int. Cl. H01L 23/02; H01L 21/00

(52) U.S. Cl. 257/686; 438/109; 257/E23.085

(57) ABSTRACT

A circuit board stack structure embedded with semiconductor components includes two circuit boards, each of which having an opening; circuit layers formed on top and bottom surfaces of the circuit boards, each of the circuit layers having a plurality of conductive structures and electrical connecting pads; two semiconductor components embedded in the openings respectively, each of the semiconductor components having a plurality of electrode pads electrically connected to a portion of the conductive structures; a plurality of conductive bumps implanted on the electrical connecting pads of at least one of the circuit boards; and a plurality of solder balls formed on the electrical connecting pads on the other of the circuit boards that is free of the conductive bumps, allowing the conductive bumps of the one of the circuit boards to be engaged with the solder balls of the other of the circuit boards.

### CROSS-REFERENCE TO RELATED APPLICATIONS

Under 35 USC 119(e), this application claims the benefit of priority to Taiwanese Patent Application No. 095120153, filed Jun. 7, 2006. All of which is incorporated herein by reference.

### BACKGROUND OF THE INVENTION

1. Field of the Invention

This invention relates to circuit board stack structures, and more particularly, to a carrier technology for integrating a semiconductor chip to a circuit board stack structure.

2. Description of Related Art

That an electric device is designed to have a compact size has becoming one of the most inevitable trends in electronic industry. With the trend toward designing a compact electronic device, a semiconductor chip have various functionalities and installed on a circuit board is required to have a high density. In general, at least two semiconductor chips electrically connected to each other by bonding wires are installed in a stack manner on a single chip carrier.

FIG. 1 is a cross sectional view of a multi-chip semiconductor package 1 disclosed in U.S. Pat. No. 5,323,060. A first semiconductor chip 12a is installed on a circuit board 11. A first bonding wire 13a electrically connects the first semiconductor chip 12a to the circuit board 11. An adhesive layer 14 is stacked on the first semiconductor chip 12a. The adhesive layer 14 is made of epoxy resin or tape. A second semiconductor chip 12b is stacked on the adhesive layer 14. A second bonding wire 13b electrically connects the second semiconductor chip 12b to the circuit board 11. The connection of the first bonding wire 13a to the first semiconductor chip 12a and circuit board 11 is performed prior to the stacking of the second semiconductor chip 12b on the adhesive layer 14. In other words, die bonding and wire bonding processes for chips on each layer are performed individually, thus adding extra manufacturing complexity. Moreover, since the first semiconductor chip 12a, adhesive layer 14 and second semiconductor chip 12b are stacked one by one on the circuit board 11, the adhesive layer 14 has to be higher than an arc of the bonding wire 13a, so as to preventing the second semiconductor chip 12b from touching the first bonding wire 13a. However, such a structure not only increases a whole thickness of the multi-chip semiconductor package 1, but is also contrary to the compactness requirement of semiconductor chips. Moreover, it is difficult to the adhesive layer 14 to have even thickness. In result, a short circuit problem that the second semiconductor chip 12 touches the first bonding wire 13a or the first bonding wire 13a touches the second bonding wire 13b occurs.

To meet the requirements of high integration for electronic devices, which have high utility performance and low height, a technique for embedding semiconductor chips in a carrier board has becoming one of the most popular techniques in the art. The semiconductor chips embedded into the carrier board can be active components or passive components. FIG. 2 is a cross sectional view of a carrier board 20 embedded with a semiconductor chip 21 according to the prior art. At least an opening 200 is formed on the carrier board 20. The opening 200 is used for receiving the semiconductor chip 21. The semiconductor chip 21 has an active surface 21a and a plurality of electrode pads 212 installed on the active surface 21a. A dielectric layer 22 is formed on the carrier board 20 and the active surface 21a of the semiconductor chip 21. A circuit layer 23 is formed on the dielectric layer 22. The circuit layer 23 comprises a plurality of conductive blind vias 231 electrically connected to the electrode pads 212 of the semiconductor chip 21. More circuit layers and dielectric layers are further stacked in accordance with a manufacturing process described above, so as to form a multi-layered circuit board.

However, in the above manufacturing process the single carrier board 20 embedded with the single semiconductor chip 21 has limited electric functionalities. More semiconductor chips 21 have to be installed on the carrier board 20 if the carrier board 20 wants to have more electric functionalities. Therefore, the carrier board 20 has to have more openings 200. Since the carrier board 20 has a limited area, the carrier board 20 cannot be installed with more opening 200, and the expansion and development of electric functionalities of the carrier board 20 is restricted.

Therefore, how to embed semiconductor chips into a circuit board to strengthen the electric requirements and functionalities of the circuit board has becoming one of the most urgent issues in the art.

### SUMMARY OF THE INVENTION

In views of the above-mentioned problems of the prior art, it is a primary objective of the present invention to provide a circuit board stack structure embedded with semiconductor components, so as to simplify a manufacturing process.

It is another objective of the present invention to provide a circuit board stack structure embedded with semiconductor components, so as to strengthen electric requirements and functionalities of a whole structure.

To achieve the above-mentioned and other objectives, a circuit board stack structure embedded with semiconductor components is provided according to the present invention. The circuit board stack structure includes at least two circuit boards, each of which has at least an opening; an upper circuit layer and an lower circuit layer respectively formed on the top surface and the bottom surface of each of the circuit boards, each of the circuit layers having a plurality of conductive structures and electrical connecting pads; two semiconductor components respectively embedded in the openings of the circuit boards, each of the semiconductor components having a plurality of electrode pads electrically connected to a portion of the conductive structures; a plurality of conductive bumps implanted on the electrical connecting pads on the top surface of at least one of the circuit boards; and a plurality of solder joints implanted on the electrical connecting pads on the bottom surface of at least one of the circuit board that is not formed with the conductive bumps, wherein the solder joints formed on the bottom surface of the one of the circuit boards are correspondingly electrically connected to the conductive bumps formed on the top surface of the other of the circuit boards, so as to form electrical connections between the circuit boards.

The circuit board may be a printed circuit board or an integrated circuit (IC) package substrate. The conductive structures may be conductive blind vias. The circuit boards may further comprise electroplated through holes electrically connected to the conductive structures, which are not electrically connected to any semiconductor components. Each of the conductive bump may be made of copper, silver, gold, nickel or lead. Furthermore, the semiconductor component may an active component or a passive component.

Compared with the prior art, the circuit board stack structure embedded with semiconductor components of the present invention include the melded conductive bump and solder joint, for stacking a plurality of carrier structures for semiconductor components, so as to simplify a manufacturing process, and thereby strengthen electric requirements and functionalities of a whole structure and overcome the drawbacks of the prior art.

### BRIEF DESCRIPTION OF DRAWINGS

The invention can be more fully understood by reading the following detailed description of the preferred embodiments, with reference made to the accompanying drawings, wherein:

FIG. 1 is a cross-sectional view of a multi-chip semiconductor package disclosed in U.S. Pat. No. 5,323,060;

FIG. 2 is a cross-sectional view of a carrier board embedded with a semiconductor chip according to the prior art;

FIG. 3A is a cross-sectional view of a circuit board stack structure embedded with semiconductor components of the preferred embodiment according to the present invention;

FIG. 3B is a cross-sectional view of a conductive bump of one circuit board engaged with a solder ball of another circuit board shown in FIG. 3A;

FIG. 4A is a decomposed schematic diagram of a circuit board stack structure embedded with semiconductor components shown in FIG. 3B; and

FIG. 4B is an assembly schematic diagram of the circuit board stack structure shown in FIG. 4A.

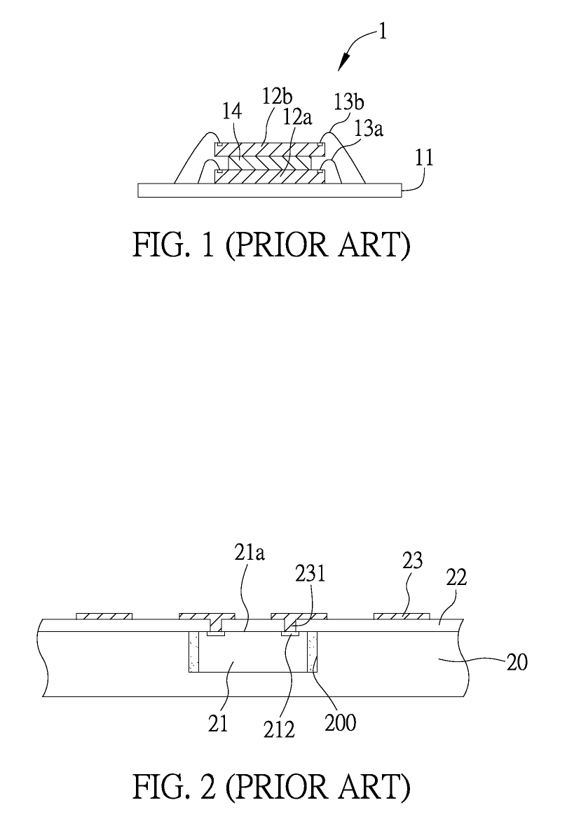

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

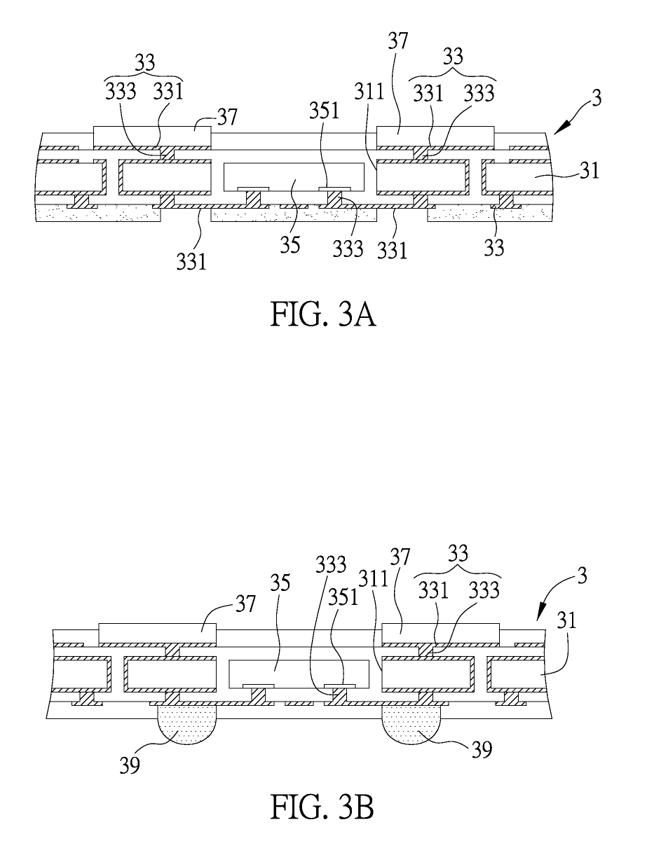

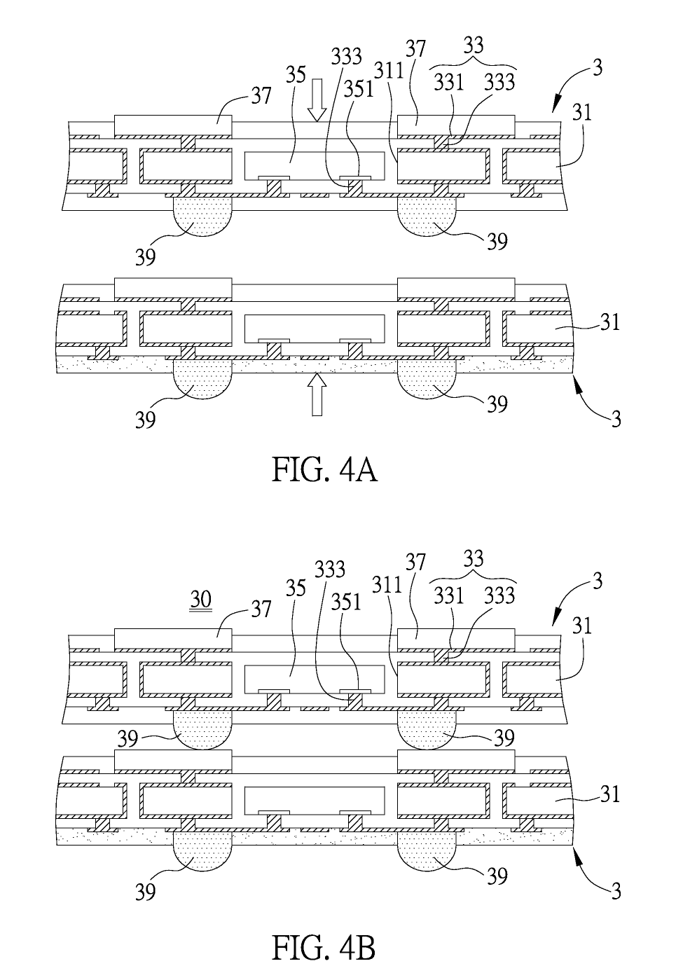

FIGS. 3A to 4B are four drawings depicted according to the preferred embodiment of a circuit board stack structure embedded with semiconductor components according to the present invention.

As shown in FIG. 3A, a carrier structure 3 having at least a semiconductor component embedded therein comprises at least a circuit board 31 having at least an opening 311, at least two circuit layers 33 respectively formed on the top and bottom surfaces of the circuit board 31, at least a semiconductor component 35 received in the opening 311 of the circuit board 31, at least one conductive bump 37 formed on the circuit layers 33 on the top surface of the circuit board 31. According to one preferred embodiment, the circuit board 31 may be a printed circuit board or an integrated circuit (IC) package substrate.

Furthermore, a plurality of electrical connecting pads 331 are respectively formed on the top and bottom surfaces on each of the circuit layers 33. A plurality of conductive structures such as conductive blind vias 333 are further formed on the circuit layer 33 and electrically connected to the electrical connecting pads 331. The circuit board 31 may further comprises a plurality of electroplated through holes (not shown) for electrically connecting to the conductive structures that are not electrically connected to the semiconductor components, so as to form electrical connections between the circuit layers on the top and bottom surfaces of the carrier structure 33.

The semiconductor component 35 may be an active component such as a central processing unit (CPU), a memory (DRAM, SRAM, SDRAM) and the like, or a passive component such as a capacitors, resistor, inductor and the like. According to one preferred embodiment, the semiconductor component 35 may comprise a plurality of electrode pads 351 electrically connected to the conductive blind vias 333 of the circuit layer 33.

Moreover, according to one preferred embodiment, the conductive bump 37 is formed on a surface of the electrical connecting pad 331 of the circuit layer 33 on the top surface of the circuit board 31, wherein the conductive bumps may be made of a material selected from the group consisting of copper (Cu), silver (Ag), gold (Au), nickel/gold (Ni—Au) and nickel/lead/gold (Ni—Pb—Au). Preferably, the conductive bump 37 is made of copper added up with any one of the foregoing materials.

Although the carrier structure 3 comprising the semiconductor component of the present embodiment mainly comprises the circuit board 31, the circuit layers 33, the semiconductor component 35 and the conductive bumps 37, alternatively, according to another preferred embodiments at least one solder ball 39 may be further implanted on a surface of one of the electrical connecting pads 331 on the circuit layer 33 on the bottom surface of the circuit board 31, as shown in FIG. 3B.

Moreover, referring to FIG. 4A, when the carrier structure 3 is to be stacked over another carrier structure to form a circuit board stack structure 30, a solder ball 39 may be implanted on the electrical connecting pad 331 of the circuit layer 33 on the bottom surface of the circuit board 31. The conductive bumps 37 and solder balls 39 are welded, so as to form electrical connection between the two carrier structures 3.

As shown in FIG. 4B, the circuit board stack structure 30 comprises at least two circuit boards 31, each of the circuit boards 31 having at least two the circuit layers 33 and at least an opening 311, wherein each of the circuit boards 31 comprises a plurality of electrical connecting pads 331 and conductive structures; a plurality of conductive bumps 37 implanted on the electrical connecting pads 331 of the circuit layers 33; at least two semiconductor components 35 embedded in the openings 311 and having at least one electrode pad 351; and a plurality of solder joints 39 formed on the electrical connecting pads 331 of one of the circuit layers 33 that is free of the conductive bump 37.

In one preferred embodiment, each of the circuit layer 33 comprises a plurality of electrical connecting pads 331 and conductive blind vias 333. The electrode pads 351 of the semiconductor components 35 are electrically connected to the circuit layers 33 via the conductive blind vias 333. Furthermore, the conductive bumps 37 are correspondingly electrically connected to the solder joints 39, so as to form electrical connection between the circuit boards 31.

Likewise, through the use of the corresponding conductive bumps 37 and the solder joints 39, a plurality of the carrier structures 3 can be stacked over each other for forming the stack structure 30 having multiple carrier structures. It is obvious that a circuit build-up structure (not shown) can be further formed on external surfaces of the two stacked circuit boards 31, so as to form a structure having multiple layers of circuit boards.

Moreover, the solder joints 39 formed on the outmost layer of the stack structure 30 may be correspondingly disposed and electrically connected to conductive bumps of a circuit board, or serve as conductive structures for electrically connecting to external electronic devices (not shown).

In summary, the circuit board stack structure having semiconductor components embedded therein comprises at least a conductive bump formed on at least one of the electrical connecting pads on at least a circuit board and disposed in position corresponding to at least a solder joint of another circuit board. The conductive bump and solder ball are welded to form a conductive path for electrically connecting a plurality of stacked circuit boards and semiconductor components embedded in the circuit boards, so as to simplify a manufacturing process, and thereby strengthen electric requirements and functionalities of a whole structure and overcome the drawbacks of the prior art.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A circuit board stack structure embedded with semiconductor components, comprising:
at least two circuit boards, each of the circuit boards having at least an opening;
at least two circuit layers respectively formed on two surfaces of each of the circuit boards, each of the circuit layers having a plurality of conductive structures and electrical connecting pads;
at least two semiconductor components received in the openings of the circuit boards and formed with a plurality of electrode pads for being electrically connected to the circuit layers via the conductive structures;
a plurality of conductive bumps implanted on the electrical connecting pads of at least one of the circuit boards; and
a plurality of solder joints implanted on the electrical connecting pads on a surface of one of the circuit board that is not formed with the conductive bumps, wherein the solder joints of one of the circuit boards are correspondingly electrically connected to the conductive bumps of the other of the circuit boards, so as to form electrical connections between the circuit boards.

2. The circuit board stack structure of claim 1, wherein the circuit board is one selected from the group consisting of a printed circuit board and IC package substrate.

3. The circuit board stack structure of claim 1, wherein the conductive bump comprises at least one selected from the group consisting of copper, silver, gold and lead.

4. The circuit board stack structure of claim 2, wherein each of the semiconductor components is one selected from the group consisting of an active component and a passive component.

5. The circuit board stack structure of claim 1, wherein the conductive structures are conductive blind vias.

6. The circuit board stack structure of claim 1, wherein each of the circuit board further comprises electroplated through holes electrically connected to the upper and lower circuit layers.
